(19) United States
(12) Patent Application Publication
(10) Pub. No.: US 2025/0260369 A1
(43) Pub. Date: Aug. 14, 2025

(54) MULTIPLE PATH AMPLIFIER CIRCUIT AND METHOD

(71) Applicant: STMicroelectronics International N.V., Geneva (CH)

(72) Inventors: Anthony Quelen, Grenoble (FR); Thierry Masson, Varces (FR)

(21) Appl. No.: 19/040,122

(22) Filed: Jan. 29, 2025

(30) Foreign Application Priority Data
Feb. 13, 2024 (FR) FR2401382

(51) Int. Cl. H03F 1/02; H02P 23/00

(52) U.S. Cl. CPC H03F 1/0288; H02P 23/00

(57) ABSTRACT

The present disclosure relates to a multipath amplifier method and circuit comprising a first and a second amplification path for an input voltage, coupled in parallel, the first path comprising a first amplifier stage, a second amplifier stage and a notch filter between a first node coupled to the second amplifier stage and a second node coupled to an output of the first amplifier stage, and a control unit configured, following detection of a change in common mode of the input voltage, for a first duration to open the first path and to couple the first node to the second node through a unity-gain amplifier.

### CROSS-REFERENCE TO RELATED APPLICATIONS

This application claims the benefit of French Patent Application No. 2401382, filed on Feb. 13, 2024, which application is hereby incorporated herein by reference.

### TECHNICAL FIELD

The present description relates generally to multiple path amplifier circuits and their operating methods.

### BACKGROUND ART

The measurement of low voltages, for example in motor supply current measurements, can be disrupted when the common mode of this voltage changes abruptly.

### SUMMARY

There is a need to reduce the disturbance time during an abrupt change in the common mode of a voltage.

One embodiment overcomes some or all of the drawbacks of known multiple path amplifier circuits.

One embodiment provides a multipath amplifier circuit comprising:
a first and a second amplification paths of an input voltage, coupled in parallel, the first path comprising a first amplifier stage, a second amplifier stage and a notch filter between a first node coupled to the second amplifier stage and a second node coupled to an output of the first amplifier stage; and
a control unit configured, following detection of a change in common mode of the input voltage, for a first duration, to open the first path and to couple the first node to the second node through a unity-gain amplifier.

One embodiment provides a method for operating a multipath amplifier circuit comprising a first and a second amplification paths of an input voltage, coupled in parallel,
the first path comprising a first amplifier stage, a second amplifier stage, and a notch filter between a first node coupled to the second amplifier stage and a second node coupled to an output of the first amplifier stage;
the method comprising, following detection of a change in common mode of the input voltage, for a first duration, operating a control unit to:
open the first path, and
couple the first node to the second node through a unity-gain amplifier.

In one embodiment, the second path is used when frequencies of the input voltage are higher than a first frequency, and wherein the first path is used when frequencies of the input voltage are lower than this first frequency.

In one embodiment, the first amplifier stage is configured to compensate for an offset voltage present at its input.

In one embodiment, the first amplifier stage comprises a first amplifier coupling a first shaping circuit, configured to modulate an input voltage of the first amplifier, and a second shaping circuit, configured to demodulate an output voltage of the first amplifier.

In one embodiment, the unity-gain amplifier is configured to implement offset compensation of its input voltage.

In one embodiment, the unity-gain amplifier is configured to copy the input voltage offset of the second amplifier stage on the second node with an offset less than or equal to 50 μV during the first duration.

In one embodiment, the unity-gain amplifier comprises:
an amplifier stage, an output of which is configured to be coupled to the second node, a first and a second differential amplifier circuits configured to in turn measure and compensate their respective voltage offset.

In one embodiment, the first and second differential amplifier circuits comprise each:
respective first inputs coupled to the second node,
respective second inputs coupled to the first node, and
respective outputs coupled to an input node of the amplifier stage.

In one embodiment, the detection of change in common mode of the input voltage is implemented by a detector of rising and/or falling edge of the common mode of the input voltage.

In one embodiment, the amplifier circuit comprises:
a fourth amplifier coupling an output node of the amplifier circuit to an output of the second amplifier stage; and
a first capacitive element coupling the output node to the output of the second amplifier stage.

In one embodiment, a second capacitive element couples the second node to the output node of the amplifier circuit.

In one embodiment, the second node is coupled to a third capacitive element.

One embodiment provides an electronic current determining device comprising a measuring resistor and an amplifier circuit as described above, wherein the input voltage of the amplifier circuit is taken between two terminals of the resistor.

One embodiment provides a control system for a motor comprising a motor and a device as described above implemented on at least one power supply phase of the motor.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates schematically an example of a motor system to which the embodiments apply;

FIG. 2 illustrates schematically circuits of the system shown in FIG. 1 according to an example;

FIG. 3 illustrates schematically circuits of the system shown in FIG. 1 according to one embodiment;

FIG. 4 illustrates schematically circuits shown in FIG. 3;

FIG. 5 illustrates a time diagram of the operation of the circuits shown in FIG. 4;

FIG. 6 illustrates a circuit shown in FIG. 3 according to one embodiment;

FIG. 7 illustrates a circuit shown in FIG. 3 according to one embodiment;

FIG. 8 illustrates a circuit shown in FIG. 3 according to one embodiment;

FIG. 9 illustrates a circuit shown in FIG. 3 according to one embodiment;

FIG. 10 illustrates a circuit shown in FIG. 9 according to one embodiment;

FIG. 11 illustrates a circuit shown in FIG. 9 according to one embodiment;

FIG. 12 illustrates a time diagram of operation of a circuit shown in FIG. 1 when a circuit shown in FIG. 3 is used; and

FIG. 13 illustrates schematically a motor system according to one embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or within 10°, and preferably within 5% or within 5°.

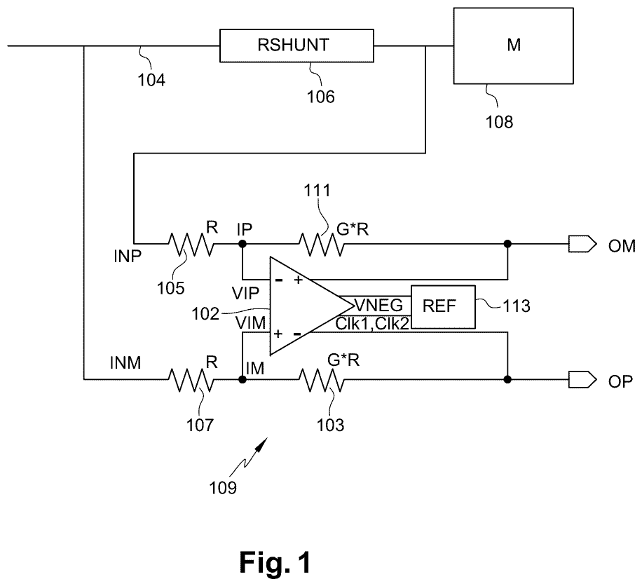

FIG. 1 illustrates schematically an example of a motor system to which the embodiments apply.

In the example shown, a motor 108 (M) is supplied by at least one phase 104 which passes through a resistor 106 (RSHUNT) of very low value. By measuring the voltage INP-INM present across this resistor 106, it is possible to deduce the value of the current flowing through the motor 108.

In the example shown, an amplifier circuit 109 is coupled, preferably connected, across the resistor 106, to amplify the voltage INP-INM, for example with a gain greater than 10 at outputs OM-OP.

The amplifier circuit 109 comprises a resistor 105 having a value R coupling a node IP to the terminal of resistor 106 that is coupled to motor 108. The amplifier circuit 109 further comprises a resistor 107 having a value R coupling a node IM to the terminal of resistor 106 that receives the phase intended for the motor 108. A resistor 111 and a further resistor 103, both with a value G*R where G is the gain, couple the node IP to the output OM and the node IM to the output OP respectively.

In the example shown, an amplifier circuit 102 has one input (denoted “−”) coupled, preferably connected, to the node IP to receive a potential VIP, and another input (denoted “+”) coupled, preferably connected, to the node IM to receive a potential VIM. The amplifier circuit 102 receives clock signals Clk1, Clk2 and a voltage VNEG from an operating unit 113 (REF). One output of circuit 102 (denoted “+”) is coupled to output OM, and another output of circuit 102 (denoted “−”) is coupled to output OP.

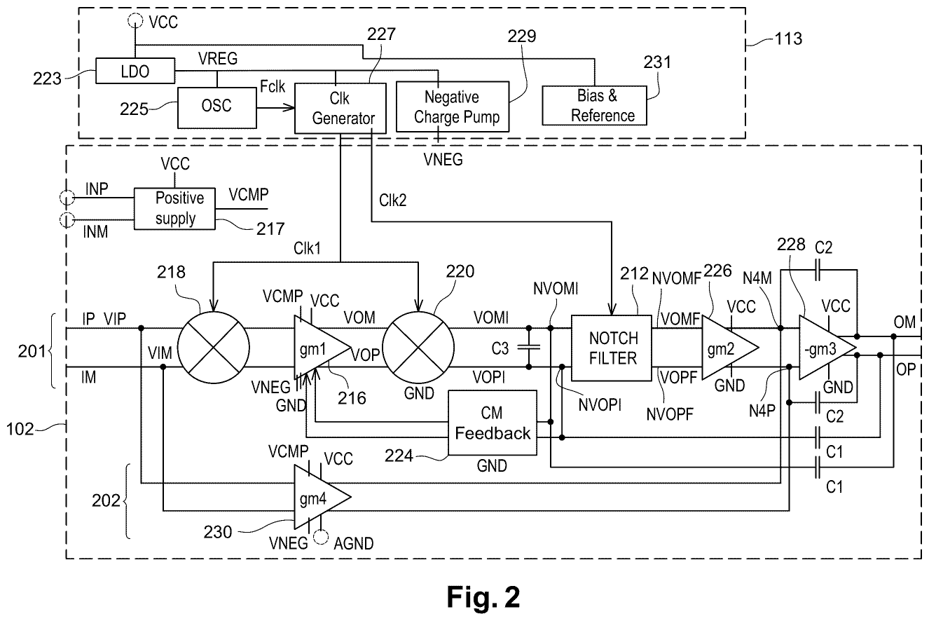

FIG. 2 illustrates schematically circuits of the system shown in FIG. 1 according to one example. In particular, FIG. 2 illustrates the circuits 113 and 102 shown in FIG. 1.

In the example shown, circuit 113 comprises a voltage rail receiving a voltage VCC. This voltage rail is coupled, preferably connected, to:
a low-drop-out (LDO) regulator circuit 223, which generates a regulated voltage VREG distributed to an oscillator 225 (OSC), a clock signal generator 227 (Clk Generator), and a negative charge pump circuit 229 (Negative Charge Pump), which generates the voltage VNEG; and
a voltage generator circuit 231 (Bias & Reference).

In the example shown, oscillator 225 provides a signal Folk to circuit 227 to generate signals Clk1 and Clk2. The signal Clk2, for example, has a frequency half that of Clk1.

The circuit 102 comprises, for example, a positive voltage generation block 217 (Positive supply) coupled, preferably connected, as input to the terminals INP, INM of the resistor 106 and also to the voltage rail VCC, and delivering as output a voltage VCMP.

Circuit 102 comprises first and second paths 201,202 for amplifying the voltage between nodes IP and IM. Each of the paths comprises one channel dedicated to processing the potential VIP received at node IP, and another channel dedicated to processing the potential VIM received at node IM.

For the sake of clarity, in the remainder of the text, a single node will refer to a node placed at the same level on both channels of the same path.

In the example shown, the two paths are coupled in parallel between node IP,IM and a node N4M,N4P. The first path 201 comprises a first amplifier 216 (gm1) which couples a first shaping circuit 218 (Chopper Modulator) and a second shaping circuit 220 (Chopper Demodulator) referenced to ground. The voltage present between the two channels of the first path at the output of amplifier 216 is VOM-VOP. These two shaping circuits receive the clock signal Clk1, and are configured to cancel the voltage offset present at the input of amplifier 216. The first shaping circuit 218 has an input coupled, preferably connected, to the node IP, IM and the second shaping circuit 220 has an output coupled, preferably connected, to a node NVOMI,NVOPI. In one example, the first amplifier 216 receives the voltage VCMP, the voltage VCC, the voltage VNEG and is also coupled, preferably connected, to ground.

In one example, the node NVOMI, NVOPI is a capacitive node, i.e. a capacitor C3 couples the two channels of the first path at the node NVOMI, NVOPI.

In the example shown, a notch filter 212 (NOTCH FILTER) couples a node NVOMF,NVOPF, which is coupled to an amplifier 226 (gm2), and the node NVOMI,NVOPI. The notch filter 212 receives signal Clk2, for example. The frequency of the signal Clk1 is, for example, several hundred kHz or even a few MHz.

The shaping circuits are configured to perform chopping, which is a continuous time modulation technique that does not cause noise aliasing. The input voltage VIP,VIM to the shaping circuit 218 first passes through the shaping circuit 218 driven by the signal Clk1. Then, the modulated signal at the output of circuit 218 is amplified with its own input offset. The ripple caused by the voltage offset at the input of amplifier circuit 216 is filtered by notch filter 212, so that a constant voltage is obtained between the two channels NVOMF-NVOPF. In various embodiments, the input voltage is for example a single-ended or differential input voltage.

Amplifier 226 receives the voltage VCC, for example, and is also coupled, preferably connected, to ground. The amplifier is coupled, preferably connected, as output to node N4M,N4P.

In the example shown, a ground-referenced feedback circuit 224 (CM Feedback), referenced to ground, couples the amplifier 216 to the node NVOMI,NVOPI. Feedback circuit 224 is configured to allow the regulation of the output common mode of the amplifier 216 around a given fixed voltage.

The second path 202 comprises an amplifier 230 (gm4) coupling node IP,IM and node N4M,N4P. The amplifier 230 receives the voltages VCMP,VCC,VNEG, and is also coupled, preferably connected, to ground. The assembly of circuits 218,220, and 212 allows an accurate amplification to be obtained, but limits the frequency of the input signal. The second path 202 thus is mainly used when the frequency of the input signal is higher than 100 kHz and by contrast for a frequency of the input signal lower than 100 kHz, the first path is mainly used.

In one example, amplifier circuit 102 comprises a fourth amplifier 228 (gm3) coupling an output node OM,OP of circuit 102 and an output of amplifier 226 which is node N4M,N4P. The amplifier 228 receives, for example, the voltage VCC and is also coupled, preferably connected, to ground.

The circuit 102 further comprises a capacitive element of value C2 coupling, for each channel respectively, node OM,OP and node N4M,N4P.

The circuit 102 further comprises a capacitive element of value C1 coupling, for each channel respectively, the node NVOMI,NVOPI and the node OM,OP.

The common mode of the voltage present on phase 104 can vary greatly in the case of a motor, for example between 0 and 120 V, and with a variation of up to around 50 V in ten nanoseconds. This common mode variation is also found on IP-IM, i.e. on the voltage VIP-VIM. However, during the abrupt common mode variation, the output OM-OP of the circuit shown in FIG. 2 varies before returning to a more stable value. The time taken to return to a voltage value within a range of +0.5% of the value before the abrupt change in common mode is greater than 5 μs. This recovery time is relatively long, due, for example, to the speed limitation due to the sampling implemented by the circuit 212.

It is necessary to lower this recovery time, for example, to approach a time of the order of μs.

To this end, the described embodiments provide that the amplifier circuit comprises a control unit configured to open the first path 201 for a first duration, following detection of a change in the common mode of the input voltage.

This enables the signal, as soon as a change in the common mode is detected, to pass entirely through the second path during the opening time of the first path, this second path being faster than the first path. The recovery time is thus reduced.

In one embodiment, the voltage offset at the input of amplifier 226 is stored during the opening of the first path. This allows the speed of the recovery time to be further improved.

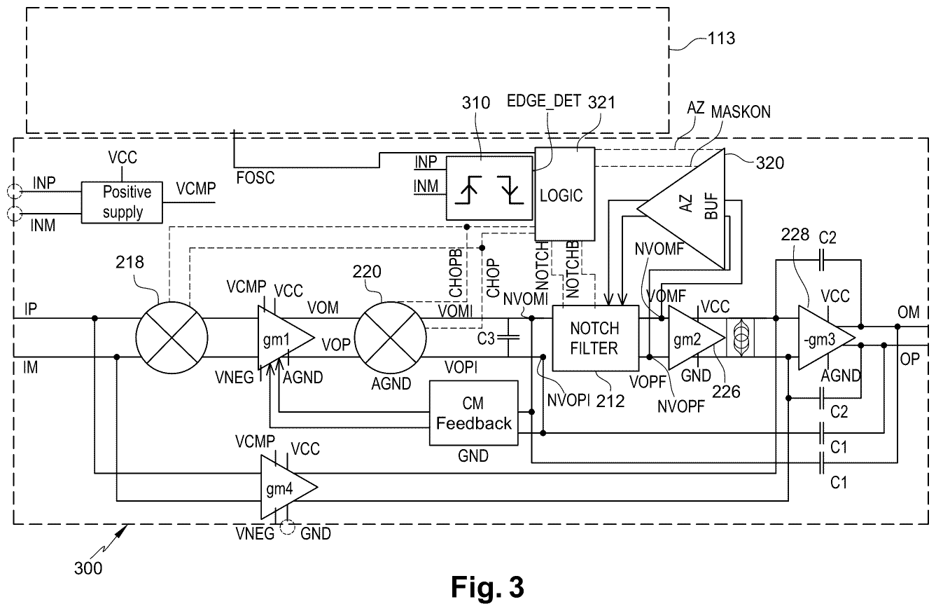

FIG. 3 illustrates schematically circuits of the system shown in FIG. 1. In particular, FIG. 3 illustrates an example of the circuit 113 and another amplifier circuit 300.

In the example shown, circuit 113 is similar to that shown in FIG. 2 except that a signal having the frequency FOSC of oscillator 225 is made available to circuit 113.

In the example shown, circuit 300 is similar to circuit 102 shown in FIG. 2, except that circuit 300 comprises a control unit 321 (LOGIC), a detector 310 for rising and/or falling edge variation of the common mode of the voltage INP-INM, and a unity gain amplifier 320 (AZ BUF). The detector 310 is coupled, preferably connected, to an input of the control unit 321. Control unit 321 is coupled, preferably connected, to unity gain amplifier 320, filter 212, and circuit 220.

When the circuit 310 detects a rising or falling edge on the common mode of the voltage INP-INM, i.e. when a rising or falling edge is detected on both terminals INP and INM at the same time, a signal EDGE_DET changes state. Depending on the state of this signal EDGE_DET, and on the basis of the signal FOSC and/or a clock signal CLK from the clock signal generator 227, the control unit 321 generates and changes the state of signals AZ, MASKON, NOTCH, NOTCHB, CHOP, and CHOPB. The signals AZ and MASKON control the unity-gain amplifier 320, the signals NOTCH and NOTCHB control the filter 212, and the signals CHOP and CHOPB control the shaping circuits 218 and 220. The signal CHOPB is the inverse of the signal CHOP, and the signal NOTCHB is the inverse of the signal NOTCH.

Following detection of a change in the common mode of the input voltage by the detector 310, the signal EDGE_DET changes state and the control unit 321, in response, opens the first path 201, i.e. opens either circuit 220 and/or filter 212 for a first duration. To do this, during this first duration, otherwise known as masking duration, the signals NOTCH and/or CHOP—and the signals CHOPB and NOTCHB respectively-are hold.

In response to the detector 310 detecting a change in the common mode of the input voltage, the control unit 321 can also change the state of the signals AZ and MASKON during the first duration (which is, for example, a few microseconds), so that the output of the unity gain amplifier 320 is connected to the node NVOMI,NVOPI. The unity-gain amplifier 320 thus stores, or copies, the voltage offset of the second amplifier stage 216 on the capacitive node NVOMI,NVOPI when the first path is opened, and feeds, or applies, it back to the node NVOMI,NVOPI during the first duration. This allows the recovery time to be reduced during a change in the common mode of the input voltage, by starting again from the voltage offset present before the first path is opened.

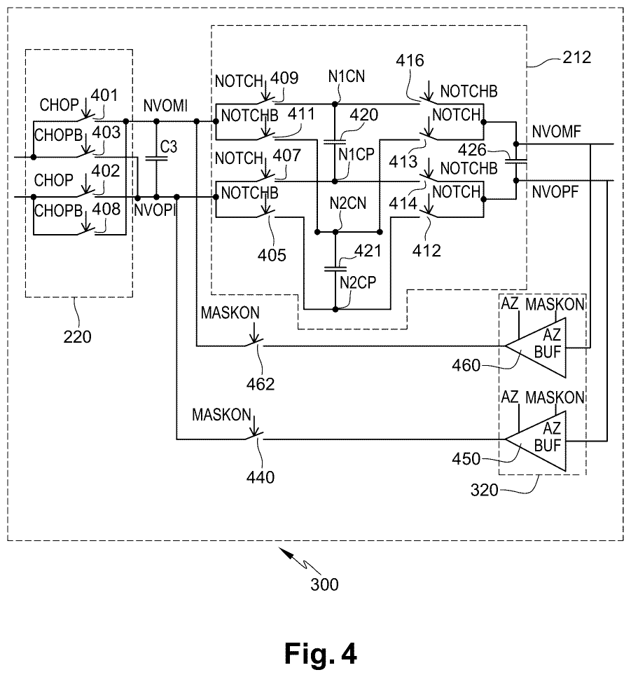

FIG. 4 illustrates schematically circuits shown in FIG. 3.

In particular, FIG. 4 illustrates circuits 212, 220, and 320 of circuit 300.

In the example shown, circuit 220 comprises:-a switch 401 controlled by the signal CHOP and coupling the channel receiving the potential VOM to the node NVOMI;
a switch 403 controlled by the signal CHOPB and coupling the channel receiving the potential VOM to the node NVOPI;
a switch 402 controlled by the signal CHOP and coupling the channel receiving the potential VOP to the node NVOPI; and
a switch 408 controlled by the signal CHOPB and coupling the channel receiving the potential VOP to the node NVOMI.

In the example shown in FIG. 4, circuit 212 comprises:
a capacitor 420 coupling node N1CN to node N1CP, a capacitor 421 coupling node N2CN to node N2CP, and a capacitor 426 coupling the two channels of node NVOMF, NVOPF;
a switch 409 controlled by the signal NOTCH and coupling node NVOMI to node N1CN;
a switch 416 controlled by the signal NOTCHB and coupling the node NVOMF to the node N1CN;
a switch 411 controlled by the NOTCHB signal and coupling the node NVOMI to the node N2CN;
a switch 413 controlled by the signal NOTCH and coupling the node NVOMF to the node N2CN;
a switch 407 controlled by the signal NOTCH and coupling the node NVOPI to the node N1CP;
a switch 414 controlled by the signal NOTCHB and coupling the node NVOPF to the node N1CP;
a switch 405 controlled by the signal NOTCHB and coupling the node NVOPI to the node N2CP;

a switch 412 controlled by the signal NOTCH and coupling the node NVOPF to the node N2CP.

In the example shown in FIG. 4, the input of unity gain amplifier 320 is coupled to the first node (NVOMF,NVOPF) and the output of unity gain amplifier 320 is coupled to the second node (NVOMI,NVOPI). Circuit 320 comprises two unity-gain amplifier stages 450 and 460, each acting on a channel of the first path. A switch 440 controlled by the signal MASKON couples the unity-gain amplifier stage 450 to the node NVOPI. The unity gain amplifier stage 450 is further coupled, preferably connected, to the node NVOPF. A switch 462 controlled by the signal MASKON couples the unity-gain amplifier stage 460 to the node NVOMI. The unity gain amplifier stage 460 is further coupled, preferably connected, to the node NVOMF.

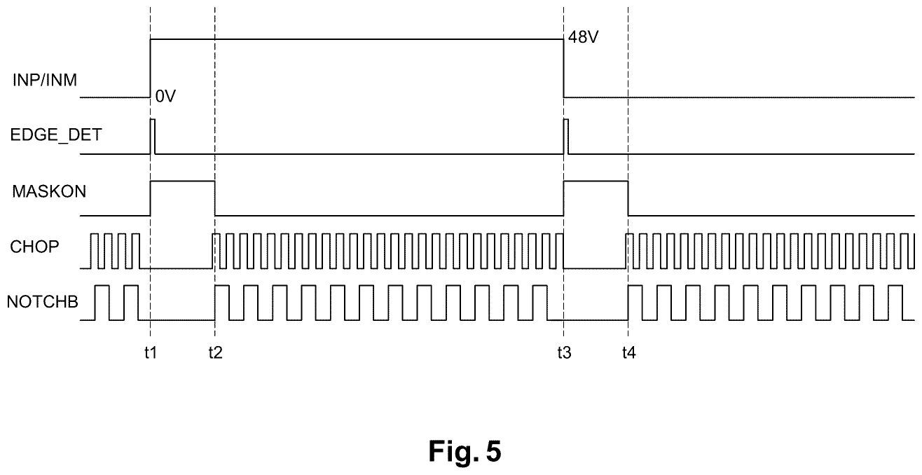

FIG. 5 illustrates a time diagram showing the operation of the circuits shown in FIG. 4. In particular, the example shown in FIG. 5 illustrates the common mode INP/INM, signal EDGE_DET, signal MASKON, signal CHOP, and signal NOTCH as a function of time.

Before a time t1, the common mode INP/INM is at 0 V, signals the EDGE_DET and MASKON are low, and the signals CHOP and NOTCH form square-wave signals with a duty cycle of 50%, the frequency of the signal CHOP being twice that of the signal NOTCH.

At time t1, the common mode voltage INP/INM changes abruptly with a rising edge from 0 V to 48 V. This causes a pulse in the signal EDGE_DET, causing the signal MASKON to go high and the signals CHOP and NOTCH to go low until time t2.

At time t2, the signal MASKON goes back low, and oscillations of signals CHOP and NOTCH resume.

At time t3, after time t2, the common mode INP/INM abruptly goes back 0 V with a falling edge, resulting in generating a pulse on the signal EDGE_DET, and setting the signal MASKON high and the signals CHOP and NOTCH low until time t4. At time t2, the signal MASKON goes back low, and oscillations of signals CHOP and NOTCH resume.

The signal AZ is not shown in FIG. 5, but has a same frequency as signal NOTCH, except it is not hold during the masking time during which the signal NOTCH is hold.

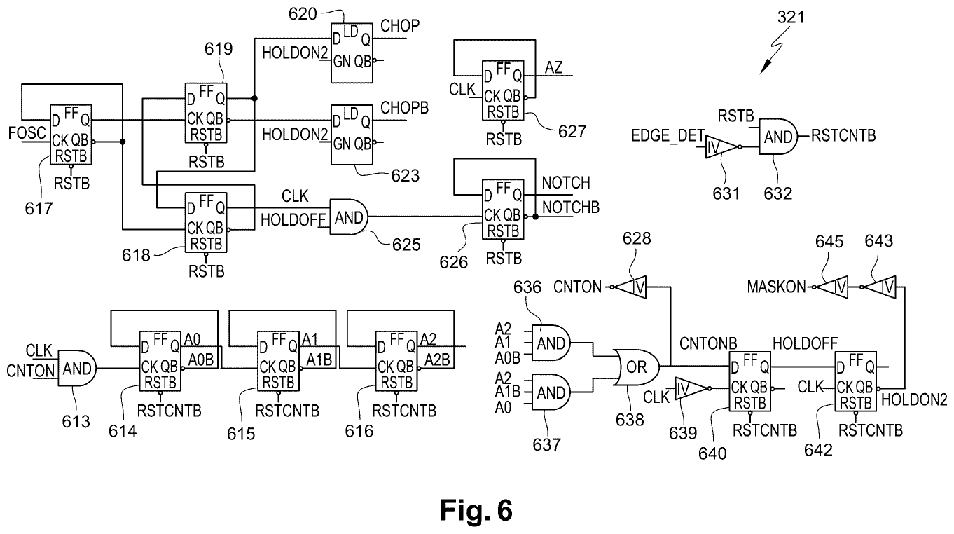

FIG. 6 illustrates a circuit shown in FIG. 3 according to one embodiment. In particular, FIG. 6 illustrates the functions of circuit 321 for generating signals NOTCH, NOTCHB, CHOP, CHOPB, and AZ.

Circuit 321 comprises a first circuit with a flip-flop 617 (FF), for example of type D, receiving the signal FOSC on a clock input CK. An output Q of this flip-flop 617 is coupled to a clock input CK of another D-type flip-flop 619. The data input D of flip-flop 619 is coupled to the inverse output QB of a further D-type flip-flop 618. The clock input CK of flip-flop 618 is coupled to the data input D and to the inverse output QB of flip-flop 617. The data input D of flip-flop 618 is coupled to the output Q of flip-flop 619 and to a data input D of a LD-type flip-flop 620. The signal state at output Q of this flip-flop 620 is the state of signal CHOP. An input GN of flip-flop 620 is configured to receive a signal HOLDON2, which when it is high for example, holds and keeps the output state Q regardless of the state of the signal on the input D. In other words, the signal HOLDON2, depending on its state, enables or disables the circuit 220. The inverse output QB of flip-flop 619 is coupled to the data input D of a LD-type flip-flop 623. The state of the signal on the output Q of this flip-flop 623 is the state of the signal CHOPB. An input GN of flip-flop 623 is configured to receive the signal HOLDON2. An output Q of the flip-flop 618 is coupled to an input of an AND-type logic gate 625, another input of which is configured to receive a signal HOLDOFF which, depending on its state, enables or disables the circuit 212. An output of logic gate 625 is coupled to the clock input CK of a D-type flip-flop the data input D of which is looped back to its inverse output QB. The state of the signal NOTCH is found on the output Q of this flip-flop 626, and the state of the signal NOTCHB is found on the inverse output QB of this flip-flop 626.

Circuit 321 comprises a second circuit comprising a D-type flip-flop 627 the data input D of which is coupled to its inverse output QB and the clock input of which is configured to receive the signal CLK. The state of the signal output on the output Q of this flip-flop 627 is the state of the signal AZ.

Flip-flops 617, 618, 619, 626, and 627 are configured to receive a reset signal RSTB.

Circuit 321 comprises a third circuit comprising an AND-type logic gate 613 configured to receive as input the state of signal CLK and the state of a signal CNTON. The output of this logic gate 614 is coupled to the clock input CK of a D-type flip-flop 614 the data input D of which is looped back to its inverse output QB. The signal on the Q output of flip-flop 614 is referred to as A0, and the signal on the inverse output QB is referred to as A0B. The third circuit further comprises two further flip-flops 615 and 616 similar to flip-flop 614. The clock input of flip-flop 615 is coupled to the output Q of flip-flop 614 and the clock input CK of flip-flop 616 is coupled to the output of flip-flop 615. The signal on the output Q of flip-flop 615 is referred to as A1 and the signal on the inverse output QB of this flip-flop is referred to as A1B. The signal on the output Q of flip-flop 616 is referred to as A2 and the signal on the inverse output QB of this flip-flop is referred to as A2B.

Flip-flops 614, 615, and 616 are configured to receive a reset signal RSTCNTB.

Circuit 321 comprises a fourth circuit comprising logic gates 636 and 637, each configured to perform an AND-type function from signals A2, A1, A0B and A2, A1B, A0 respectively. The respective outputs of logic gates 636 and 637 are coupled to the inputs of a logic gate 638 configured to perform a logic function of OR-type from the outputs of logic gates 636 and 637. The output CNTONB of logic gate 638 is coupled to an inverter 628 the output of which gives the signal CNTON. The output of logic gate 638 is further coupled to the input D of a D-type flip-flop 640 a clock input CK of which is configured to receive the signal CLK inverted with an inverter 639. The output Q of this flip-flop 640 gives the signal HOLDOFF and is coupled to the input D of another D-type flip-flop 642 the clock input of which is configured to receive the signal CLK. The inverse output QB of flip-flop 642 gives the signal HOLDON2 and is coupled to two inverters in series 631,632 to give the signal MASKON.

The circuit 321 further comprises a fifth circuit having an inverter 631 configured to receive the signal EDGE_DET and coupled, preferably connected, to an input of an AND-type logic gate 632 receiving on another input the signal RSTB. An output of logic gate 632 is signal RSTCNTB.

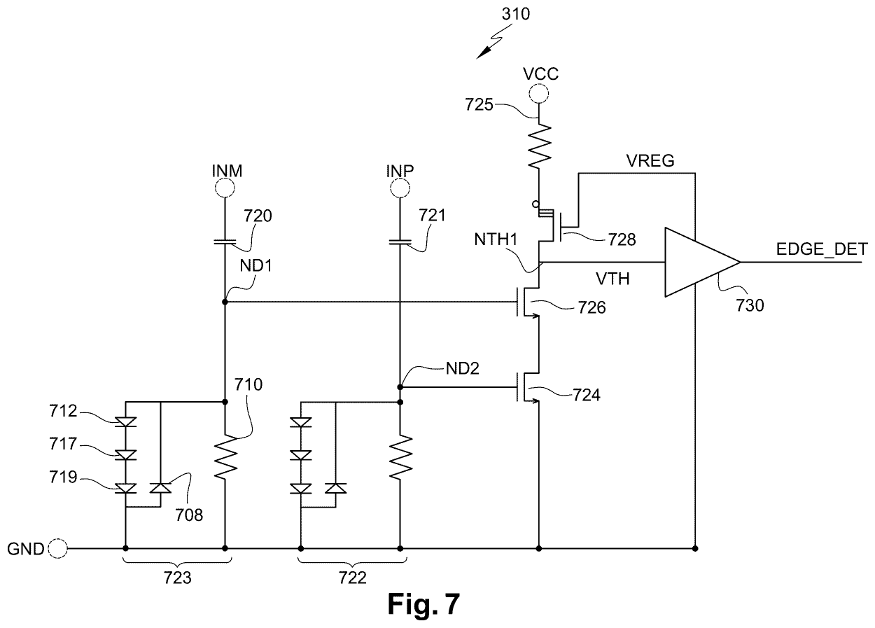

FIG. 7 illustrates a circuit shown in FIG. 3 according to one embodiment. In particular, FIG. 7 illustrates an example embodiment of the circuit 310 to detect the rising edge of the common mode voltage between INP and INM.

In the example shown, a capacitor 720 couples the node INM to a node ND1, and another capacitor 721 couples the node INM to a node ND2.

The example shown comprises a first branch 723 having: a resistor 710 coupling node ND1 to ground GND; three diodes in series 712,717, and 719 coupling node ND1 to ground; and a diode 708, placed in reverse with respect to diodes 712,717,719, which has its cathode coupled to node ND1 and its anode coupled to ground. The example shown also comprises a second branch 722 similar to the first branch 723, but where the node ND2 replaces the node ND1.

The node ND1 is coupled, preferably connected, to a control node of an NMOS transistor 726, and the node ND2 is coupled, preferably connected, to a control node of an NMOS transistor 724. A conduction node of transistor 724 is coupled, preferably connected, to ground and a conduction node of transistor 726 is coupled, preferably connected, to a node NTH1. Transistors 724 and 726 share a common conduction node.

In the example shown, a transistor 728 is coupled, preferably connected, to the voltage rail VCC via a resistor 725. Transistor 728 has a conduction node coupled, preferably connected, to node NTH1 and a control node coupled, preferably connected, to a trigger 730 such as a Schmitt trigger. The control node of transistor 728 receives the voltage VREG. The amplifier 730 is also coupled, preferably connected, to node NTH1 as input, and is referenced to ground. An output of amplifier 730 is the signal EDGE_DET.

When a rising edge is detected concurrently on INM and INP, this creates a pulse on the signal EDGE_DET at the output of the amplifier 730.

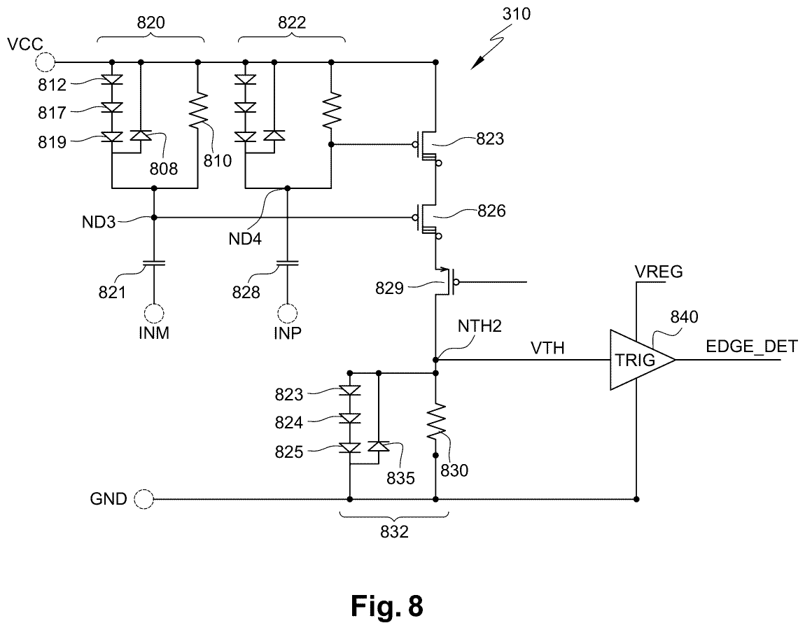

FIG. 8 illustrates a circuit shown in FIG. 3 according to one embodiment. In particular, FIG. 8 illustrates an example embodiment of circuit 310 to detect a falling edge of the common mode voltage between INP and INM.

In the example shown, a capacitor 821 couples the node INM to a node ND3, and another capacitor 828 couples the node INM to a node ND4.

The example shown comprises a first branch 820 having: a resistor 810 coupling node ND3 to the voltage rail VCC; three diodes 812,817,819 in series coupling node ND1 to the voltage rail VCC; and a diode 808, placed in reverse with respect to diodes 812,817,819, which has its cathode coupled to the voltage rail VCC and its anode coupled to node ND3. The example shown also includes a second branch 822 similar to the first branch 820, but where the node ND4 replaces the node ND3.

Node ND3 is coupled, preferably connected, to a control node of a PMOS transistor 826, and node ND4 is coupled, preferably connected, to a control node of a PMOS transistor 823. A conduction node of transistor 823 is coupled, preferably connected, to the voltage rail VCC, and a conduction node of transistor 826 is coupled, preferably connected, to a node NTH2 via a PMOS transistor 828. Transistors 826 and 823 share a common conduction node.

The example shown comprises a further branch 832 having: a resistor 830 coupling the node NTH2 to ground; three diodes 823,824,825 in series coupling the node NTH2 to ground; and a diode 835, placed in reverse with respect to the diodes 823,824,825, which has its cathode coupled to the node NTH2 and its anode coupled to ground.

In the example shown, a trigger 840, such as a Schmitt trigger, is coupled, preferably connected, as input to node NTH2 and referenced to ground. The trigger 840 also receives the voltage VREG. An output of the trigger 840 is the signal EDGE_DET.

When a falling edge is detected concurrently on INM and INP, this creates a pulse on the signal EDGE_DET at the output of the trigger 840.

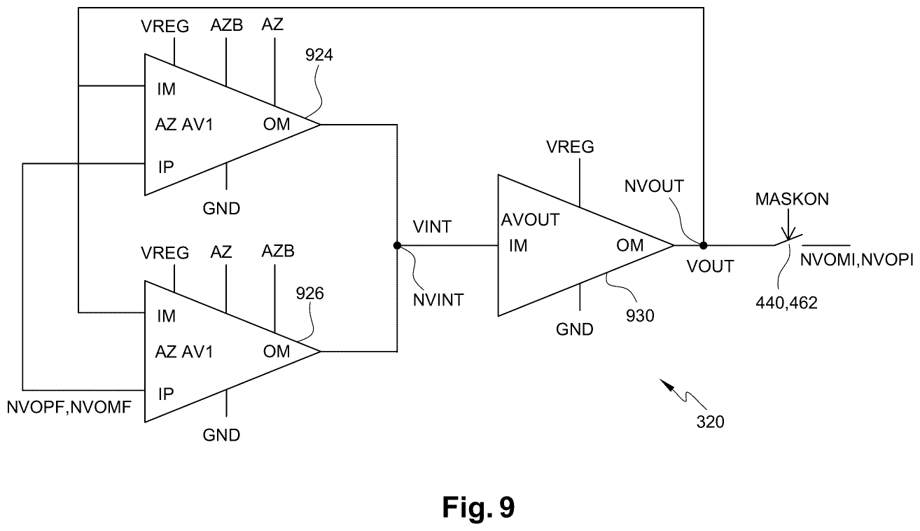

FIG. 9 illustrates a circuit shown in FIG. 3 according to one embodiment. In particular, FIG. 9 illustrates an embodiment of circuit 320.

In the example shown, the unity-gain amplifier 320 comprises an amplifier stage 930 (AVOUT) an output node NVOUT of which is configured to be coupled to the node NVOMI or NVOPI, respectively, via the respective switches 440 or 462. The amplifier stage 930 is coupled, preferably connected, to the voltage rail VREG and is referenced to ground.

Amplifier 320 further comprises first and second differential amplifier circuits 924,926 (AZ AV1), respective input nodes IM of which are coupled to node NVOMI, respectively NVOPI, and respective further input nodes IP of which are coupled to node NVOMF, respectively NVOPF. Respective output nodes OM of amplifier circuits 924,926 are coupled to the same input node NVINT of amplifier stage 930 (AVOUT). Circuits 924,926 are coupled, preferably connected, to voltage rail VREG, are referenced to ground, and are configured to receive the state of signals AZ and AZB which is the inverse of signal AZ. Circuits 924,926 receive signals AZ and AZB in a reverse way, and are thus used in turn. As one among these two circuits is used to output the following voltage on VOUT, the other one measures its input voltage offset to be able to compensate it later. Alternating use of circuits 924 and 926 is performed at the frequency of signal AZ.

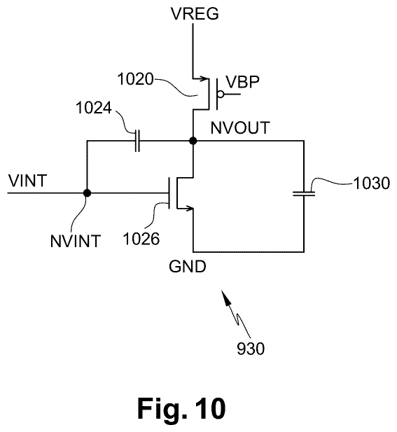

FIG. 10 illustrates a circuit shown in FIG. 9 according to one embodiment.

In particular, FIG. 10 illustrates an example embodiment of the circuit 930.

In the example shown, a capacitor 1024 couples the node NVINT to the node NVOUT, and a capacitor 1030 couples the node NVOUT to ground. The node NVINT is also coupled, preferably connected, to a control node of an NMOS transistor 1026, one conduction node of which is coupled, preferably connected, to ground and another conduction node of which is coupled, preferably connected, to the node NVOUT. A PMOS transistor 1020, the control node of which is controlled by a voltage VBP, couples the node NVOUT to the voltage rail VREG.

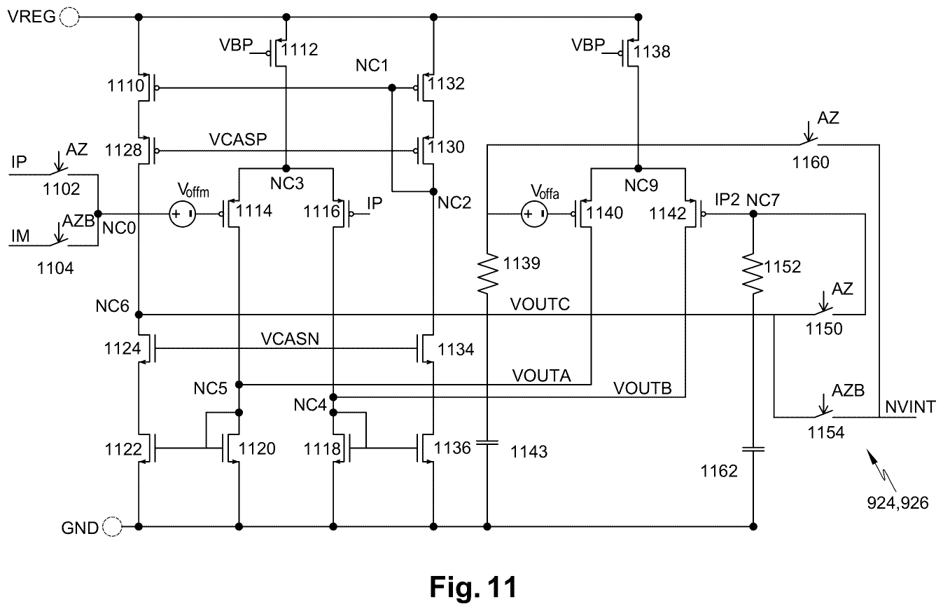

FIG. 11 illustrates a circuit shown in FIG. 9 according to one embodiment. In particular, FIG. 11 illustrates an embodiment of circuits 924, 926.

In the example shown, nodes IP and IM are coupled to a node NC0 via a switch 1102 controlled by signal AZ and a switch 1104 controlled by signal AZB respectively.

The voltage rail VREG is coupled to ground by two PMOS transistors 1110,1128 and two NMOS transistors 1124,1122 coupled in series. Transistors 1128 and 1124 have a common conduction node referred to as NC6.

A PMOS transistor 1112, the control node of which is configured to receive the voltage VBP, couples the voltage rail VREG to a node NC3. A PMOS transistor 1114 and an NMOS transistor 1120 in series couple node NC3 to ground. A PMOS transistor 1116 and an NMOS transistor 1118 in series also couple the node NC3 to ground. Transistor control node 1116 is configured to receive the signal present on IP and transistor control node 1114 is configured to be coupled, preferably connected, to node NC0. The control node of transistor 1122 is coupled, preferably connected, to the control node of transistor 1120.

The voltage rail VREG is also coupled to ground via two PMOS transistors 1132,1130 and two NMOS transistors 1134,1136 in series. The control node of transistor 1136 is coupled, preferably connected, to the control node of transistor 1118; the control node of transistor 1134 is coupled, preferably connected, to the control node of transistor 1124; the control node of transistor 1130 is coupled, preferably connected, to the transistor control node 1128; and the control node of transistor 1132 is coupled, preferably connected, to the control node of transistor 1110. The conduction node NC2, common to transistors 1130 and 1134, is coupled, preferably connected, to a node NC1 which is the control node of transistor 1132. The conduction node NC5, common to transistors 1120 and 1114, is coupled, preferably connected, to the control node of transistor 1122. The conduction node NC4, common to transistors 1118 and 1116, is coupled, preferably connected, to the control node of transistor 1118.

A PMOS transistor 1138, controlled by the signal VPB, couples a node NC9 to the voltage rail VREG. A PMOS transistor 1140 couples node NC5 to node NC9. A PMOS transistor 1142 couples node NC4 to node NC9.

The control node of transistor 1140 is coupled to node NVINT via a switch 1160 controlled by signal AZ. The control node of transistor 1140 is further coupled to ground via a resistor 1139 in series with a capacitor 1143.

The control node NC7 of transistor 1142 is coupled to ground via a resistor 1152 in series with a capacitor 1162. The control node of transistor 1142 is further coupled to node NVINT via a switch 1150 controlled by signal AZ in series with a switch 1154 controlled by signal AZB. Switch 1150 is further coupled, preferably connected, to conduction node NC6 common to transistors 1124 and 1128.

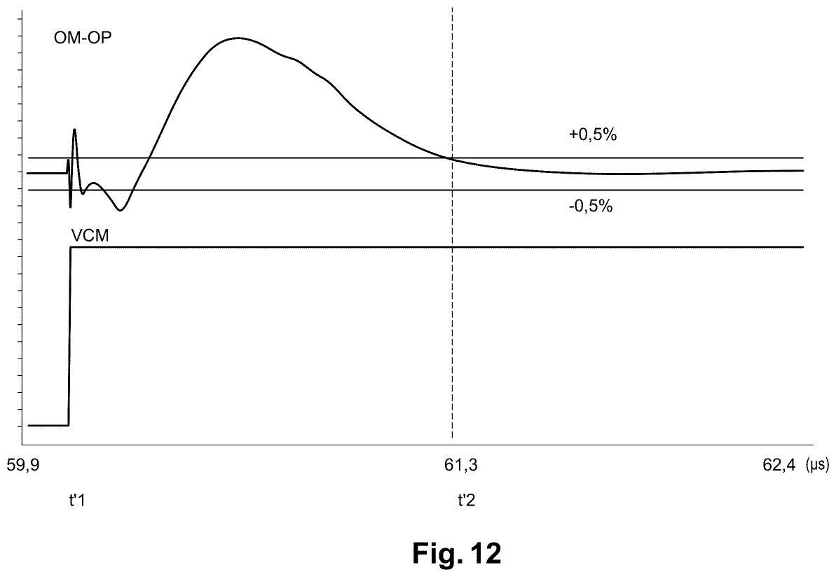

FIG. 12 illustrates a time diagram of the operation of the circuit shown in FIG. 3 when a circuit shown in FIG. 3 is used. In particular, FIG. 12 illustrates the output voltage OM-OP of the amplifier circuit 300 as well as the common mode voltage between INP and INM.

Before a time t′1, the common mode voltage INM/INP is 0 V and the output voltage is stable at 3.5 V.

At time t′1, the common mode voltage INM/INP abruptly goes to 48 V, creating output voltage instability as well as a temporary overshoot.

At time t′2, 1.3 μs after time t′1, the output voltage goes back a value range within +0.5% of the value before the common mode voltage INM/INP changes. The recovery time is therefore improved by the circuit 300 shown in FIG. 3 compared with the recovery time of the circuit 102 shown in FIG. 2.

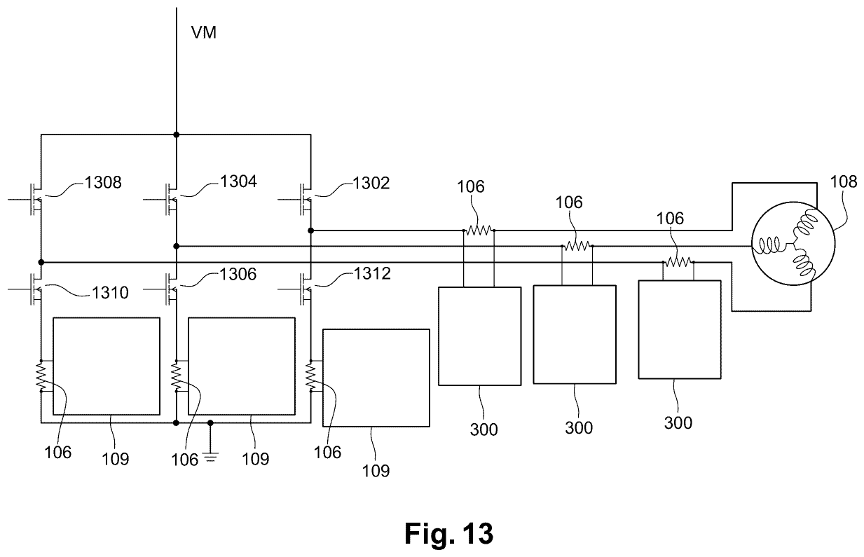

FIG. 13 illustrates schematically a motor system according to one embodiment. The system comprises a control circuit which supplies the motor 108 with three phases. The current flowing through each phase is measured, for example, by a resistor 106, across which the circuit 300 is connected.

The control circuit comprises, for example, three parallel branches coupling a voltage rail VM to ground. Each branch comprises two power transistors, respectively referred to as 1302,1312; 1304,1306; 1308,1310. The conduction node common to the transistors of the same branch is coupled, preferably connected, to one of the motor phases.

To measure the current in each of these branches, a resistor 106 is inserted between transistor 1312 and ground, and/or between transistor 1306 and ground, and/or between transistor 1310 and ground. A circuit similar to circuit 109 with circuit 300 is then connected across each resistor 106.

Such a control circuit enables precise current measurements to be performed, even during voltage changes on individual phases.

Various embodiments and variants have been described. Those skilled in the art will understand that certain features of these embodiments can be combined and other variants will readily occur to those skilled in the art. In particular, even if the unity gain amplifier 320 is associated, in FIG. 3, with the detector 310 and the control unit 321, those skilled in the art could envisage implementing only the detector and the control unit 321. In addition, even though the detection of rising and falling edges is described in separate FIGS. 7 and 8, the detector 310 may comprise both these circuits.

Finally, the practical implementation of the embodiments and variants described herein is within the capabilities of those skilled in the art based on the functional description provided hereinabove. In particular, concerning the amplifier stage formed by circuits 216, 218, 220, which is configured to compensate for an offset voltage present at its input, it is possible to replace circuits 218 and 220 by an assembly with automatic compensation of the input voltage offset (Auto Zero).

1. A multipath amplifier circuit comprising:
a first amplification path of an input voltage, the first amplification path comprising a first amplifier stage, a second amplifier stage and a notch filter between a first node coupled to the second amplifier stage and a second node coupled to an output of the first amplifier stage; and
a second amplification path of the input voltage, coupled in parallel with the first amplification path;
wherein the first amplifier stage is configured, following detection of a change in a common mode of the input voltage, for a first duration, to open the amplification first path and to couple the first node to the second node through a unity-gain amplifier.

2. The multipath amplifier circuit according to claim 1, wherein the multipath amplifier circuit is configured to use the second amplification path in response to frequencies of the input voltage being higher than a first frequency, and use the first amplification path in response to the frequencies of the input voltage being lower than the first frequency.

3. The multipath amplifier circuit according to claim 1, wherein the first amplifier stage is configured to compensate for an offset voltage present at its input.

4. The multipath amplifier circuit according to claim 3, wherein the first amplifier stage comprises a first amplifier coupling a first shaping circuit, configured to modulate a first input voltage of the first amplifier, and a second shaping circuit, configured to demodulate an output voltage of the first amplifier.

5. The multipath amplifier circuit according to claim 1, wherein the unity-gain amplifier is configured to implement offset compensation of its input voltage.

6. The multipath amplifier circuit according to claim 5, wherein the unity-gain amplifier is configured to copy an input voltage offset of the second amplifier stage on the second node with a second offset less than or equal to 50 μV during the first duration.

7. The multipath amplifier circuit according to claim 5, wherein the unity-gain amplifier comprises:
a third amplifier stage having an output coupled to the second node; and
first and second differential amplifier circuits configured to, in turn, measure and compensate their respective voltage offsets.

8. The multipath amplifier circuit according to claim 7, wherein the first and second differential amplifier circuits each comprises:
respective first inputs coupled to the second node;
respective second inputs coupled to the first node; and
respective outputs coupled to an input node of the third amplifier stage.

9. The multipath amplifier circuit according to claim 1, further comprising a detector performing the detection of the change in the common mode of the input voltage by detecting a rising edge and/or a falling edge of the common mode of the input voltage.

10. The multipath amplifier circuit according to claim 1, further comprising:
a fourth amplifier coupling an output node of the multipath amplifier circuit to an output of the second amplifier stage; and
a first capacitive element coupling the output node to the output of the second amplifier stage.

11. The multipath amplifier circuit according to claim 10, further comprising a second capacitive element coupling the second node to the output node of the multipath amplifier circuit.

12. The multipath amplifier circuit according to claim 1, wherein the second node is coupled to a third capacitive element.

13. The multipath amplifier circuit according to claim 1, wherein an input of the unity gain amplifier is coupled to the first node and an output of the unity gain amplifier is coupled to the second node.

14. A method for operating a multipath amplifier circuit having first and second amplification paths of an input voltage, coupled in parallel, the first amplification path having a first amplifier stage, a second amplifier stage, and a notch filter between a first node coupled to the second amplifier stage and a second node coupled to an output of the first amplifier stage, the method comprising:
detecting a change in a common mode of the input voltage, for a first duration; and
after the detecting the change in the common mode:
opening, by a control unit of the multipath amplifier circuit, the first amplification path; and
coupling, by the control unit, the first node to the second node through a unity-gain amplifier.

15. The method according to claim 14, further comprising:
using, by the multipath amplifier circuit, the second amplification path in response to frequencies of the input voltage being higher than a first frequency; and
using, by the multipath amplifier circuit, the first amplification path in response to the frequencies of the input voltage being lower than the first frequency.

16. The method according to claim 14, further comprising compensating, by the first amplifier stage, for an offset voltage present at its input.

17. The method according to claim 16, wherein the first amplifier stage comprises a first amplifier coupling a first shaping circuit to a second shaping circuit, and the method further comprises:
modulating, by the first shaping circuit, a first input voltage of the first amplifier; and
demodulating, by the second shaping circuit, an output voltage of the first amplifier.

18. The method according to claim 14, further comprising implementing, by the unity-gain amplifier, offset compensation of its input voltage.

19. The method according to claim 14, wherein the detecting the change in the common mode of the input voltage comprises detecting, by a detector, a rising edge and/or a falling edge of the common mode of the input voltage.

20. A system comprising:
a measuring resistor having two terminals; and
a multipath amplifier circuit comprising:
a first amplification path of an input voltage taken between the two terminals of the measuring resistor, the first amplification path comprising a first amplifier stage, a second amplifier stage and a notch filter between a first node coupled to the second amplifier stage and a second node coupled to an output of the first amplifier stage; and
a second amplification path of the input voltage, coupled in parallel with the first amplification path;
wherein the first amplifier stage is configured, following detection of a change in a common mode of the input voltage, for a first duration, to open the amplification first path and to couple the first node to the second node through a unity-gain amplifier.

21. The system according to claim 20, further comprising a motor, wherein the measuring resistor is disposed in line on a power supply phase of the motor.
